(19) United States
(12) Patent Application Publication
(10) Pub. No.: US 2007/0058354 A1
(43) Pub. Date: Mar. 15, 2007

(54) System and method for insertion, retention and extraction of a card-let printed circuit board, without protective hardware into and from a motherboard

(75) Inventors: Michael F. Scanlon, Poughkeepsie, NY (US); Wade H. White, Hyde Park, NY (US)

Correspondence Address: SCULLY SCOTT MURPHY & PRESSER, PC, 400 GARDEN CITY PLAZA, SUITE 300, GARDEN CITY, NY, 11530, US

(73) Assignee: INTERNATIONAL BUSINESS MACHINES CORPORATION, ARMONK, NY (US)

(21) Appl. No.: 11/225,412

(22) Filed: Sep. 13, 2005

(51) Int. Cl. H05K 7/14; H05K 7/18

(52) U.S. Cl. 361/801

(57) ABSTRACT

An arrangement for the insertion, retention and extraction into and from a motherboard back plane of at least one card-let printed circuit board without protective hardware, in order to be able to ensure the accurate alignment between mating connectors of these components. Furthermore, provided is a method facilitating the insertion, retention and extraction of a card-let printed circuit board of the type described, by utilizing the inventive arrangement.

### BACKGROUND OF THE INVENTION

1. Field of the Invention

The present invention relates to an arrangement for the insertion, retention and extraction into and from a motherboard back plane of at least one card-let printed circuit board without protective hardware, in order to be able to ensure the accurate alignment between mating connectors of these components. Furthermore, the invention is also directed to a method facilitating the insertion, retention and extraction of a card-let printed circuit board of the type described, by utilizing the inventive arrangement.

In essence, implementing the insertion and positioning of pluralities of card-lets into a motherboard back plane which contains receiving spaces for the installation of respectively each card-let, necessitates that the card-lets be accurately aligned therewith when inserted therein in order to ensure that connectors, which are to mate or contact between the respective card-let and the motherboard back plane connections are properly seated so as to avoid any operative failure while concurrently ensuring the reliability thereof. Moreover, once each card-let is installed in the motherboard back plane, provision must be made for retaining the card-let in its appropriate inserted and retained position so as to prevent the occurrence of any inadvertent disengagement between the mating connectors of the card-let and the mother board components. Moreover, there must also be provided a capability that each respective card-let may be easily removed or withdrawn from its retented position in the space provided therefore in the motherboard back plane, and in facilitating the extraction thereof without the risk of any damage being sustained by the generally unprotected and fragile connectors or other electronic or operative components which may be located on the card-let or contained in the motherboard back plane.

2. Discussion of the Prior Art

Currently, in the technology, provision is made for the insertion and engagement of a daughter board, having electronic components and terminal portions mounted thereon and contacts arranged along an edge thereof, into a socket of a housing representing a motherboard, and wherein engagement features or clamping structure is provided for latching the daughter board in an operative position.

In that connection, reference may be made to Yamada, et al., U.S. Pat. No. 6,466,452 B2, in which a pair of daughter cards are mounted onto an electronic socket of a motherboard housing structure, and also electronically attaches the daughter cards to a printed circuit board (PCB) on the motherboard. Latches on the motherboard are adapted to provide retention of the daughter cards to the motherboard, and once manually pressed into engageable positions by being tilted from an angled into a horizontal coaxial orientation relative to the motherboard, the latches hook into slots, which are provided on the daughter cards, thereby locking the components together. Moreover, also provided in the patent are elastic members as part of an electronic socket, which enables alignment and additional retention between the components, whereby as each respective daughter card is inserted and connected to the motherboard, a mechanical assist cam latches to a metal or plastic stop bracket which is mounted to each respective daughter board. The prior art makes no provision for the insertion of a plurality of card-lets, which mount electronic components and connectors into recesses or spaces within a housing comprising a motherboard back plane, the latter of which facilitates the insertion and operative attachment of pluralities of card-lets in respective receiving spaces.

### SUMMARY OF THE INVENTION

Accordingly, pursuant to the present invention, with the aid of a cam latch and a stop bracket, which is mounted on a the card-let, the latter can be installed by being inserted into one of the spaces provided in a motherboard back plane containing electrical contacts and electronic components. In this connection, the card-let is aligned with the space into which it is to be inserted through the intermediary of card guides which are attached to a cage structure of the motherboard back plane, and wherein respectively several card-lets can be inserted into various receiving spaces in operative contacts with a motherboard printed circuit board, and with latching cam devices enabling the card-lets to be retained once in position within the spaces in the motherboard back plane. This is a structure in which the invention enables the insertion of smaller sized card-lets in the absence of protective hardware to be inserted into, aligned and retained within a higher level motherboard electronic circuit assembly.

Accordingly, pursuant to the present invention, there is provided at least one card-let which is adapted to be inserted into a motherboard back plane, wherein the card-let is provided with a stop bracket including two independent cam latches mounted on respectively the card side edges opposite a connector. The motherboard back plane cage is provided with card guides which are mounted to sidewalls or uprights of the cage structure, and wherein the respective card-let is adapted to be slid into the space defined by the card guides so as to have the latter line up with the card edges of the card-let mounting mechanical cam latches. The mechanical cam latches on the card-let are rotatable 90° inwardly from each card-let top card edge, enabling the card-let to move forwardly into the motherboard back plane with the side card edges sliding within the card guides at the right and left side edges of the space and the card-let is moved forward until a cam feature on the back plane cage engages the cam latches and stops the card-let from moving further forward. At that point, electrical connectors mounted on the card-let are mated and engaged with the connectors and/or electronic components contained in the spaces provided in the motherboard back plane, and the card-let is biased forwardly a final integer until the cam feature provided on the back plane cage stops the mechanical cam latches on the card-let from moving further upon engagement therewith. Thereafter, the mechanical cam latches provided on the card-let are rotated simultaneously inwardly into a home position so that each cam latch, which through a hook-like shape engages the cam features located at the side edges of the motherboard cage, such as upright elements, is rotated, biasing the card-let into its furthest forwardly advanced position, and the mating connectors of the components are reliably engaged. The card-let is prevented from any inadvertent rearward movement when the mating connectors are fully engaged and the mechanical cam latches are folded together against the stop brackets thereby retaining the card-let in place. In order to extract the card-let from the inserted position in the motherboard back plane, the cam latches are disengaged from the stop bracket by being each rotated outwardly to a 90° position, and the card-let is adapted to be extracted from the back plane disengaged by being pulled out from its respective space.

Accordingly, it is an object of the present invention to provide an arrangement for the insertion, retention and extraction of a card-let printed circuit board without any protective hardware into and from suitable spaces provided in a motherboard back plane.

Another object of the present invention is to provide an arrangement enabling the insertion of pluralities of card-lets of the type described into respective spaces provided for in a motherboard back plane and incorporating mechanical cam latching means for ensuring the insertion and retention of the card-let so as to provide for appropriate and reliable operative contact and mating between electrical connectors and components of the respective card-let and those provided for in the motherboard back plane.

A still further object of the present invention is to provide a novel mechanical cam latching arrangement on a card-let adapted to enable the insertion and retention thereof in an operative position of the card-let in a motherboard back plane and wherein a latching engagement of the cam latching arrangement with cam engaging structure on a cage for the back plane will provide for the appropriate electrical connections between connectors on the card-let and the motherboard back plane.

Yet another object of the present invention is to provide for a method for the insertion, retention and extraction of a card-let printed circuit board of the type described into a motherboard back plane utilizing the mechanical cam latching arrangement of the invention.

### BRIEF DESCRIPTION OF THE DRAWINGS

Reference may now be made to the following detailed description of a preferred embodiment of the invention, taken in conjunction with the accompanying drawings; in which:

FIG. 1 prospectively illustrates, generally diagrammatically, a motherboard back plane structure adapted to receive a plurality of card-let printed circuit boards pursuant to the invention;

FIG. 2 illustrates a perspective representation of a card-let printed circuit board pursuant to the invention, which is adapted to be inserted into a space provided for in the motherboard back plane; and

FIG. 3 illustrates an enlarged perspective view of the card-let printed circuit board of FIG. 2 pursuant to the present invention.

### DETAILED DESCRIPTION OF THE INVENTION

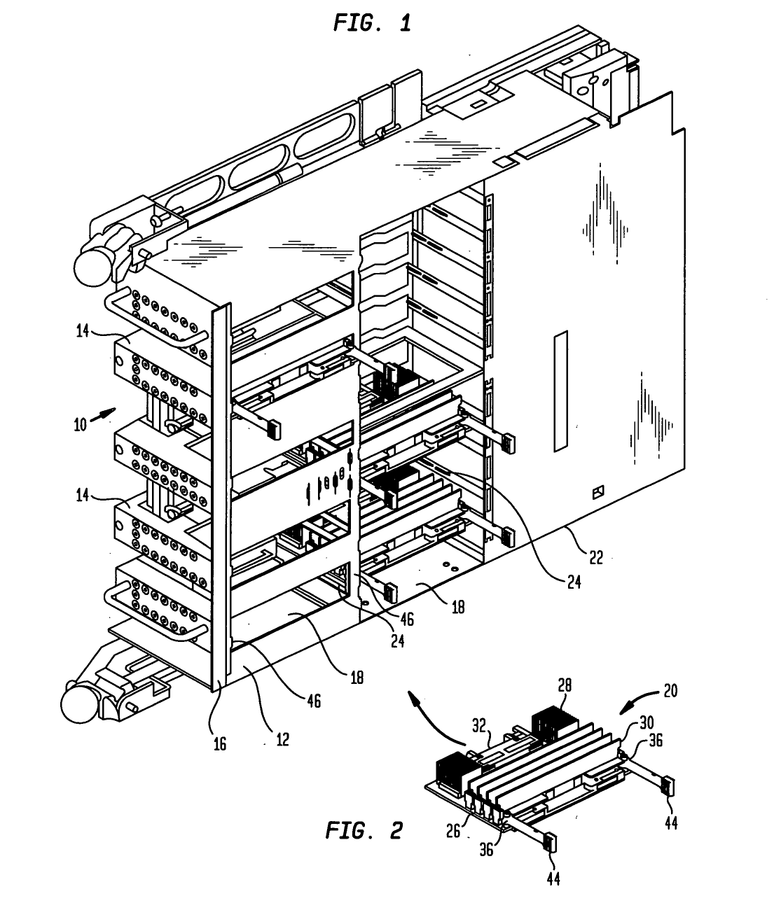

Referring now in specific detail to the drawings, and particularly FIG. 1, there is illustrated a motherboard back plane 10 comprising a housing 12 constituted of a cage configuration having supporting panels 14 and upstanding columns 16 which provide for shelving spaces 18 for receiving a plurality of card-let printed circuit boards 20, i.e., one in each of the spaces, as described further on hereinbelow.

The housing structure 12 for the motherboard back plane 10 incorporates a hingedly connected front door panel 22, which is adapted to be closed subsequent to the insertion of respective card-lets 20 into the various spaces 18 provided for therein.

As illustrated, the motherboard back plane 10 includes side guide members 24 of the cage, which are adapted to slidingly receive corresponding edges and guides 26 of the card-let printed circuit boards 20 when the latter are inserted into therewith associated spaces 18 in an axially horizontally sliding movement, as represented by arrow A between FIGS. 1 and 2.

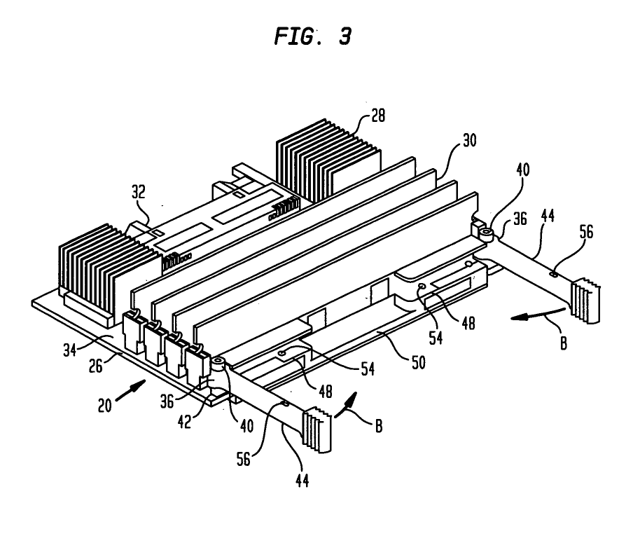

Each of the card-lets 20, as represented in FIGS. 2 and 3 of the drawings, typically includes a plurality of various (diagrammatically illustrated) electronic components 28 and printed circuit cards 30 and electrical connectors 32, which are adapted to contactingly mate with suitable connectors (not shown) in the respective spaces 18 provided for in the motherboard back plane 10 so as to complete the electrical connections and electronic circuits therebetween, as is known in the technology.

In order to ensure that there has been implemented a proper insertion and retention of the card-let printed circuit board 20 in the respective space 18, which is provided therefor in the motherboard back plane 10, as shown in more specific detail in FIG. 3, the rear side edges of the upper surface 34 of the card-let printed circuit board 20 are provided with a pair of cam latches 36, each of which includes a mechanical camming structure in generally a hook-shape at forward pivot post ends 40 at the rear end portion 42 of each of the respective card-let printed circuit boards 20.

Upon the card-let printed circuit board 20 being inserted into an associated receiving space 18 in the motherboard back plane 10, as may be required for intended connections, the guides 24 provided for in the motherboard back plane 10 or cage are adapted to receive the edges or guides 26 of the card-let printed circuit board 20, and the latter is slid forwardly into the space interior until the electrical contacts or connectors 32, which are provided for at the leading end thereof are adapted to be in electrical contact or communication with suitable electrical contacts in a reliable mating relationship, as provided for in the motherboard back plane 10.

Upon the card-let printed circuit board 20 having been fully inserted into space 18, each of the mechanical cam latches 36 are rotated 90° inwardly by means of their outwardly extending lever-like handles 44, in the direction of arrows B causing the hook shaped cam latch structure 36 at the leading end of each of the cam latch levers 44, which rotate about their respective pivot posts 40, to engage a cam engaging structure on the front uprights 46 in the form of strips of sheet metal uprights on the motherboard back plane cage edges at each side of a respective space 18. Upon the mechanical cam latches being moved or pivoted inwardly toward each other, the handles or levers 44 contact stop brackets 48 formed at the rear surface 50 of the card-let printed circuit board 20, with the interengaging cam arrangement causing the card-let printed circuit board to be biased slightly forwardly so as to ensure electrical contact has been established between the electrical contacts on the motherboard back plane 10 and those on the card-let printed circuit board 20. In order to also to concurrently prevent any extraction of the card-let in an inadvertent manner due to the latching engagement between the pivoted mechanical cam latches 36 and the strip-shaped cam engaging structure 46 on the motherboard back plane housing structure, the stop brackets 48 are provided with detents or apertures 54 which are engageable with cooperating raised or gripping elements 56 formed on the levers 44. This will latch the levers 44 into inwardly pivoted positions thereof.

Thereafter, the door panel or panels 22 on the motherboard back plane 10 may be closed during normal operation of the components in the motherboard back plane.

In order to release and extract a respective card-let printed circuit board 20 from receiving space 18 in the motherboard back plane 10 in which it is located, it is merely necessary to open the front door panel 22, as illustrated in FIG. 1 of the drawings, and pivot the mechanical cam latches 36 by means of handles or levers 44 outwardly into each a 90° extended position, disengaging elements 54 and 56, so as to locate the levers in a parallel spaced relationship relative to each other, as shown in FIGS. 2 and 3 of the drawings. This will result in the camming structures 36, 46 disengaging, and resultingly enable a manual pulling out and extraction of the card-let printed circuit board 20 from the motherboard back plane 10.

The foregoing in a clear and simple manner, through a unique and simple arrangement and method enables the insertion, retention and subsequent extraction of card-let printed circuit boards 20 mounting diverse electronic and electrical components from a motherboard back plane 10, which is not at all disclosed nor suggested in the current state-of-the-art. The arrangement and method ensures the appropriate positioning and electrical interconnections between the components and connectors arranged on pluralities of card-let printed circuit boards 20 and a multi-spaced motherboard back plane 10.

While the present invention has been particularly shown and described with respect to preferred embodiments thereof, it will be understood by those skilled in the art that the foregoing and other changes in forms and details may be made without departing from the scope and spirit of the present invention. It is therefore intended that the present invention not be limited to the exact forms and details described and illustrated, but fall within the scope of the appended claims.

What is claimed is:

1. An arrangement for the insertion, retention and extraction of at least one card-let printed circuit board into and from at least one space in a motherboard back plane and facilitating an accurate alignment between mating connectors and electrical contacts on said components; comprising:
cam engaging structure formed on a housing portion of said motherboard back plane proximate said at least one space; and
cam latching means provided on said at least one card-let printed circuit board for grippingly engaging said cam engaging structure upon insertion of said card-let printed circuit board into said at least one space and biasing said mating connectors and electrical contacts into operative engagement.

2. An arrangement as claimed in claim 1, wherein said cam engaging structure comprises upright elements formed proximate front side edges of said at least one space, said cam latching means on said card-let printed circuit board including rotatable cam latches for grippingly engaging said upright elements upon insertion of said at least one card-let printed circuit board into said at least one space in said motherboard back plane.

3. An arrangement as claimed in claim 2, wherein said cam latching means comprises a pair of pivotable levers rotatably fastened to side rear edge portions on the upper surface of said at least one card-let printed circuit board, said pivotable levers being rotatable towards each other for causing the cam latches provided at leading ends thereof to grippingly engage said upright elements and for releasing said upright elements upon outward rotation away from each other.

4. An arrangement as claimed in claim 3, wherein stop brackets are formed on a rear surface of said at least one card-let printed circuit board for limiting the inward rotational movement of said pivotable levers upon said cam latches grippingly engaging said upright elements.

5. An arrangement as claimed in claim 4, wherein cooperatively engageable means are formed on each of said stop brackets and said levers for releasably latching said levers in the inwardly rotated positions.

6. An arrangement as claimed in claim 1, wherein said at least one space and said at least one card-let printed circuit board are provided with cooperative guide means for guidance of said at least one card-let printed circuit board during insertion into and extraction from said at least one space in said motherboard back plane.

7. An arrangement as claimed in claim 4, wherein said pivotable levers are each pivotable through an angular displacement of 90° between an inward position producing a gripping engagement between said cam latches and upright elements, and an outwardly rotated position in which said pivotable levers extend in parallel with each other from said at least one card-let printed circuit in a position of producing a disengagement between said cam latches and said upright elements.

8. An arrangement as claimed in claim 3, wherein said upright elements are sheet metal strips located at the front side edges of said at least one space, said cam latches being rotatable about said sheet metal edges for locking engagement therewith upon insertion of said at least one card-let printed circuit board into said at least one space in said motherboard back plane.

9. An arrangement as claimed in claim 2, wherein each said cam latch possesses a hook-shaped configuration for grippingly encompassing a respective one of said upright elements during engagement between said cam latching structure and said cam latching means.

10. An arrangement as claimed in claim 1, wherein said motherboard back plane includes a plurality of said spaces, each said space being adapted to have respectively one said card-let printed circuit board inserted therein.

11. A method for the insertion, retention and extraction of at least one card-let printed circuit board into and from at least one space in a motherboard back plane and facilitating an accurate alignment between mating connectors and electrical contacts on said components; said method comprising:
providing cam engaging structure on a housing portion of said motherboard back plane proximate said at least one space; and
providing cam latching means on said at least one card-let printed circuit board for grippingly engaging said cam engaging structure upon insertion of said card-let printed circuit board into said at least one space and biasing said mating connectors and electrical contacts into operative engagement.

12. A method as claimed in claim 11, wherein said cam engaging structure comprises upright elements formed proximate front side edges of said at least one space, said cam latching means on said card-let printed circuit board including rotatable cam latches for grippingly engaging said upright elements upon insertion of said at least one card-let printed circuit board into said at least one space in said motherboard back plane.

13. A method as claimed in claim 12, wherein said cam latching means comprises a pair of pivotable levers rotatably fastened to side rear edge portions on the upper surface of said at least one card-let printed circuit board, said pivotable levers being rotatable towards each other for causing the cam latches provided at leading ends thereof to grippingly engage said upright elements and for releasing said upright elements upon outward rotation away from each other.

14. A method as claimed in claim 13, wherein stop brackets are formed on a rear surface of said at least one card-let printed circuit board for limiting the inward rotational movement of said pivotable levers upon said cam latches grippingly engaging said upright elements.

15. A method as claimed in claim 11, wherein said at least one space and said at least one card-let printed circuit board are provided with cooperative guide means for guidance of said at least one card-let printed circuit board during insertion into and extraction from said at least one space in said motherboard back plane.

16. A method as claimed in claim 14, wherein said pivotable levers are each pivotable through an angular displacement of 90° between an inward position producing a gripping engagement between said cam latches and upright elements, and an outwardly rotated position in which said pivotable levers extend in parallel with each other from said at least one card-let printed circuit in a position for producing a disengagement between said cam latches and said upright elements.

17. A method as claimed in claim 16, wherein cooperatively engageable means on each of said stop brackets and levers releasably latch said levers in the inwardly rotated positions.

18. A method as claimed in claim 13, wherein said upright elements are sheet metal strips located at the front side edges of said at least one space, said cam latches being rotatable about said sheet metal edges for locking engagement therewith upon insertion of said at least one card-let printed circuit board into said at least one space in said motherboard back plane.

19. A method as claimed in claim 12, wherein each said cam latch possesses a hook-shaped configuration for grippingly encompassing a respective one of said upright elements during engagement between said cam latching structure and said cam latching means.

20. A method as claimed in claim 11, wherein said motherboard back plane includes a plurality of said spaces, each said space being adapted to have respectively one said card-let printed circuit board inserted therein.
